(19) United States
(12) Patent Application Publication
(10) Pub. No.: US 2010/0273320 A1
(43) Pub. Date: Oct. 28, 2010

(54) DEVICE AND METHOD FOR SELECTIVELY DEPOSITING CRYSTALLINE LAYERS USING MOCVD OR HVPE

(76) Inventors: Johannes Käppeler, Würselen (DE); Dietmar Schmitz, Aachen (DE)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(21) Appl. No.: 12/528,408

(22) PCT Filed: Feb. 21, 2008
(86) PCT No.: PCT/EP08/52110

§ 371 Date: Aug. 24, 2009

(30) Foreign Application Priority Data
Feb. 24, 2007 (DE) 10 2007 009 145.3

(51) Int. Cl. H01L 21/205; C23C 16/46; H01L 21/365; C30B 25/10

(52) U.S. Cl. 438/507; 118/725; 257/E21.108; 257/E21.463

(57) ABSTRACT

The invention relates to a device for depositing one or more layers, in particular crystalline layers, on one or more substrates, in particular crystalline substrates (6), which are situated on a susceptor (3) in a process chamber (2) of a reactor (1). A process chamber wall (4) that can be actively heated by a process chamber heating unit (11) lies opposite the susceptor (3) that can be actively heated by the susceptor heating unit (11). The device is provided with a gas inlet organ (7) for introducing process gases into the process chamber and the process chamber heating unit (11) has a coolant channel (13) and is situated at a distance from the exterior (18) of the process chamber wall (4) during the active heating of the latter (4). The aim of the invention is to also allow the device to be used with hybrid technology. To achieve this, the process chamber wall (4) can be selectively actively heated and also actively cooled, the coolant channel (13) acting as a cooling unit (12) for the process chamber wall. The distance between the cooling unit (12) for the process chamber wall and said wall (4) can be altered from heating position that is at a distance to a cooling position by means of a displacement unit, which is in particular designed as a lifting unit.

The invention relates to an apparatus for depositing one or more layers, in particular crystalline layers, on one or more substrates, in particular crystalline substrates, disposed on a susceptor in a process chamber of a reactor, wherein a process chamber wall that can be actively heated by a process chamber heating device lies opposite the susceptor that can be actively heated by a susceptor heating device, and a gas inlet element is provided for introducing process gases into the process chamber, and the process chamber heating device having a coolant channel and being situated at a distance from the exterior of the process chamber wall during the active heating of said process chamber wall.

The invention also relates to a method for depositing one or more layers, in, particular crystalline layers, on one or more substrates (6), in particular crystalline substrates, disposed on a susceptor in a process chamber of a reactor, the susceptor being actively heated to a susceptor temperature of more than 1000° C. and, for depositing the layer by the HVPE process, the process chamber wall that lies opposite the susceptor being actively heated to a process chamber wall temperature which lies in the range of +/−200° C. above or below the susceptor temperature, process gases which comprise at least a hydride and a metal halide being introduced into the process chamber by means of a gas inlet element, and a further layer being deposited in the same process chamber by the MOCVD process at a time before or after the deposition of the layer by the HVPE process, the process gases comprising at least a hydride and an organometallic compound.

An apparatus of this kind is already known from DE 102 47 921 A1. There, the susceptor is formed by a floor of a process chamber. Disposed in the floor of the process chamber are a multiplicity of substrate holders, which, while being supported on a gas cushion, are respectively driven in rotation by the gas stream forming the gas cushion. On each substrate holder there is a substrate. Above the susceptor, a process chamber wall that forms the process chamber ceiling extends at a distance from the susceptor and parallel thereto. The process chamber is formed in a substantially rotationally symmetrical manner. A gas inlet element by which process gases can be introduced into the process chamber protrudes into the center of the process chamber. It is intended for an HVPE crystal deposition process to be carried out in the process chamber. For this purpose, elements of the third main group in the form of metal chlorides are introduced into the process chamber. In addition, elements of the fifth main group in the form of hydrides are introduced into the process chamber together with a carrier gas. The susceptor is heated from below by means of a water-cooled RF heater. For this purpose, it consists of an electrically conductive material, namely of coated graphite. The process chamber wall lying opposite the susceptor is likewise actively heated. Here, too, the energy is introduced by way of an RF field into the process chamber ceiling, which is made of conductive material, for example graphite, by means of an RF heating coil.

An MOCVD reactor is known from DE 10217806 A1. There, the process gases are introduced into the process chamber from above, through an actively cooled process chamber ceiling, by way of a gas inlet element. The susceptor lying opposite the process chamber ceiling is heated from below by means of an RF heating coil. The distance between the process chamber ceiling and the susceptor can be varied.

DE 10133914 A1 describes a reactor for depositing one or more layers by the MOCVD process. Here, too, the process is carried out in a process chamber with a cold process chamber ceiling, opposite which there lies a heated susceptor. In the center of the process chamber there is a gas inlet element, through which an organometallic compound and a hydride are respectively introduced in separate feed channels, together with a carrier gas.

U.S. Pat. No. 6,733,591 B2 discloses an apparatus with which layers can be effected, according to choice, by the MOCVD process or the HVPE process in a single process chamber. The process chamber can be operated both in the “hot-wall reactor” mode and in the “cold-wall reactor” mode. In the “cold-wall reactor” mode, only trimethyl gallium and a hydride, for example arsine or NH₂, are introduced into the process chamber. If the reactor is operated in the “hot-wall” mode, HCl is introduced into the process chamber in addition to the TMG, so that the gallium atoms of the decomposed TMG can bond with the HCl to form gallium chloride. With the apparatus described there and with the process described in U.S. Pat. No. 6,218,280 B1, it is intended to use the HVPE process, that is to say the “hot-wall” process, to deposit a thick central layer on a thin MOCVD layer previously deposited by the “cold-wall” process. This thick layer is then covered by a thin layer, once again deposited by the MOCVD process, so that a gallium nitrite substrate material is created.

U.S. Pat. No. 6,569,765 likewise discloses a hybrid deposition system, in which, according to choice, either a substrate holder or the entire wall of a process chamber can be heated in order to allow either an MOCVD process or an HVPE process to be carried out in the process chamber.

JP 1111 7071 A1 discloses a CVD reactor in which the temperature of the gas inlet element and of the susceptor can be controlled separately from each other.

EP 12 52 363 B1 already discloses a process chamber of a CVD coating device in which the temperature of the gas inlet element can be controlled with the aid of coolant flowing through channels.

U.S. Pat. No. 4,558,660 discloses a CVD apparatus in which the heating of the walls of the process chamber is effected by way of lamps which are disposed in a water-cooled housing.

An MOCVD cold-wall reactor is known from WO 00/04205. The cold reactor wall is actively cooled by a jacket through which cooling water flows. In order to clean the process chamber, and in particular the cooled wall, a process chamber wall heater is provided, allowing the process chamber wall to be brought to a temperature that causes gaseous HCl introduced into the process chamber to act with an etching effect there.

U.S. Pat. No. 5,027,746 discloses an MOCVD reactor in which a process chamber wall is cooled by means of cooling fluid.

It is an object of the invention to develop an apparatus such as that known from the initially cited DE 1024 7921 A1 in such a way that it is also possible to operate it with hydride technology.

The object is achieved by the invention specified in the claims; each claim represents an independent way of achieving the object and it being possible to combine each claim with any other claim.

The apparatus is substantially distinguished by the fact that the susceptor on which the substrate lies, if need be on a substrate holder, can be heated by a susceptor heating device in both types of process. The susceptor may form the floor of a process chamber. The susceptor heating device is preferably an RF heating coil, which builds up an RF field that generates eddy currents in the susceptor consisting of graphite. As a result, the susceptor heats up, and with it the substrate. Lying opposite the susceptor is a process chamber wall. This preferably runs parallel to the preferably circular disk-shaped susceptor. This process chamber wall, which forms a process chamber ceiling if the susceptor is disposed at the bottom, can, according to choice, be actively heated or actively cooled. Heating of the process chamber wall is possible, so that the surface thereof facing the process chamber can assume a temperature that is ±200° C. of the susceptor temperature. However, as an alternative to being heated, the process chamber wall can also be cooled by means of an independent cooling device. The cooling ensures that, in spite of the radiant heat emitted by the heated susceptor, the temperature of the process chamber wall remains far below the susceptor temperature. The temperature of the process chamber wall can be kept to values far below a temperature that lies at least 200° lower than the susceptor temperature. Various preferred variants as to how the active cooling or the active heating of the process chamber wall can be carried out are provided. The process chamber wall is preferably heated in the same way as the susceptor, that is to say by means of an RF heating coil. This is disposed at a distance from the process chamber wall. The RF field produced by the RF coil generates, eddy currents in the process chamber wall, preferably consisting of graphite, the eddy currents heating up the process chamber wall. In this HVPE mode, the process chamber wall temperature can be varied in a range that is ±200° with respect to the susceptor temperature, by suitable choice of the energy fed in. The susceptor temperature can be varied in a range between 400 and 700° C. In the case of the MOCVD process, in which gallium nitrite is preferably deposited, the susceptor temperature preferably varies in the range between 1400° C. and 1600° C. If other crystals, in particular III-V crystals, are deposited on a substrate, the temperature may also lie below that, for example be only 1000°. If an MOCVD process is to be carried out within the process chamber, it is then necessary, to avoid parasitic growth on the process chamber wall, for the latter to be cooled to temperatures far below the susceptor temperature. The susceptor temperatures differ for different steps of the growing process. The susceptor temperature may, for example, lie between 400 and 500° C. for steps of low-temperature growth. In this temperature range, GaN nucleation layers are deposited for example on silicon substrates by means of MOCVD. GaN high-temperature layers, on the other hand, are deposited at susceptor temperatures of between 950° C. and 1200° C. For depositing InGaN by the MOCVD process, susceptor temperatures are set between 750° C. and 850° C. In the case of growth of AlGaN, the susceptor temperatures lie in the range between 950° C. and 1700° C. When depositing AlN, the susceptor temperatures lie in the range between 1300° C. and 1700° C. The process chamber wall heating device, which is formed by the RF heating coil, may at the same time form the process chamber wall cooling device. The RF heating coil is formed by a spiral hollow body. Cooling water flows through the cavity of the hollow body. The cooling water serves during the heating of the process chamber wall as a coolant for the RF heating coil, to avoid it heating up to inadmissible temperatures. This cooling device can also be used in the case of the MOCVD process for cooling the process chamber wall. For this purpose, the distance between the RF heating coil and the exterior of the process chamber wall is altered. This takes place by means of a displacement device. With this displacement device, the RF heating coil is brought closer to the exterior of the process chamber wall or the process chamber is displaced in the direction of the RF heating coil. The distance between the RF heating coil and the exterior of the process chamber wall is preferably reduced to zero. In this case, the heat transfer from the process chamber wall to the cooling device does not take place by thermal radiation or thermal conduction by way of a gas, but by heat dissipation through direct contact. In particular cases, it may be adequate if the distance between the RF heating coil and the exterior of the process chamber wall is very small. The distance is reduced either by a displacement of the process chamber wall in the direction of the RF heating coil or by a displacement of the RF heating coil in the direction of the process chamber wall. If the process chamber wall is the process chamber ceiling, the vertical displacement of the process chamber ceiling may take place until there is surface contact with the underside of the RF heating coil, by the process chamber ceiling being raised by means of a lifting device. The latter is preferably formed by a ceiling carrier. To ensure that sufficient heat transfer takes place from the process chamber wall into the cooling channels, the planar undersides of the RF heating coil lie in surface contact on the exterior of the process chamber wall. Spring elements may be provided, pressing the individual portions of the RF coil against the exterior of the process chamber wall. These spring elements may be compression springs. These compression springs press against the individual turns of the RF coil, for example with an electrical insulator in between. A multiplicity of such spring elements may be provided. They may, for example, be disposed such that they are distributed at equal angular intervals. For example, the spring elements may be disposed at angular intervals of 90°. The spring elements may be supported on a corresponding mount, which can be lowered and raised again together with the RF coil. In an alternative, the process chamber wall may have cooling channels through which a cooling medium flows. The cooling medium is preferably a material that is liquid both in the “cold-wall mode” and in the “hot-wall mode”. Liquid gallium or liquid indium come for example into consideration as the coolant. The susceptor has the form of a circular disk and can be rotated about its axis. Recesses may be provided in the susceptor. Substrate holders may lie in these recesses. The substrate holders may lie on a gas cushion and be driven in rotation by the gas cushion. A substrate may lie on each of the plurality of substrate holders. The substrate holders are heated by means of a single susceptor heating device. The susceptor consequently forms a heatable wall of the process chamber, opposite which lies another wall that can be heated or cooled, according to choice. The process chamber wall, which by choice can be actively cooled or actively heated, preferably forms a process chamber ceiling. The process chamber ceiling is horizontally aligned and likewise has the form of a circular disk. It has a central opening, through which a gas inlet element protrudes. With this gas inlet element, the process gases can be introduced into the process chamber. The process chamber is flowed through horizontally by the process gases. The direction of flow is preferably the radial direction. In the MOCVD mode, in which the process chamber ceiling is actively cooled, which may take place either by passing a coolant through cooling channels of the process chamber ceiling or by bringing the latter into contact with the cooling coil formed by the RF heating coil, suitable process gases are introduced into the process chamber through channels of the gas inlet element that are separate from one another. For depositing gallium nitrite, trimethyl gallium and NH₃ for example are introduced into the process chamber. For depositing gallium nitrite, the susceptor temperature is approximately 900° to 1200° C. The temperature of the process chamber ceiling is then at most 700° C. It preferably lies in the range between 300° and 400° C. If an HVPE process step is to be carried out in the process chamber, the process chamber ceiling is no longer actively cooled. If the cooling takes place by means of a coolant which is passed through cooling channels of the process chamber ceiling, the coolant flow is stopped. If the cooling takes place by the RF heating coil with water flowing through it, the coil is at a spacing from the process chamber ceiling. A distance of a few millimeters is sufficient here. To carry out the HVPE process in the process chamber, not only the susceptor but also the process chamber ceiling lying opposite the susceptor are actively heated. The temperature of the substrate holder may reach values between 1000° and 1400° C., and preferably temperatures up to 1600° C. The temperature of the process chamber ceiling is heated to a process chamber ceiling temperature in the range of ±200° above or below the respective susceptor temperature. A hydride and a metal halide are used for the deposition. This metal halide is preferably a metal chloride. Instead of chlorine, however, iodine or bromine or fluorine may also be used. HCl is used to produce the methyl chloride. The formation of the metal chloride, for example the formation, of gallium chloride, may take place within the process chamber. The gallium source selected may either be liquid gallium, over which HCl is passed to form gallium chloride there, or else trimethyl gallium or some other volatile gallium compound, which is introduced into the process chamber, where it can pyrolytically decompose. The gallium thereby released reacts with HCl to form gallium chloride. In the case of the HVPE mode, that is to say with the process chamber wall heated, the temperature gradient between the susceptor and the opposite process chamber wall is flat. The temperature gradient may rise or fall, but it may also be zero. In the case of the MOCVD process, there is a very great temperature gradient. The MOCVD process may, however, also be carried out with the process chamber ceiling heated. It is even possible, and also provided in a preferred variant of the method, that small amounts of a halide are admixed with the process gas in the case of the MOCVD process. Here, too, apart from the preferred chlorine, this halide may be fluorine, iodine or else bromine. However, HCl is preferably admixed with the process gases. This takes place, however, in an amount with which there is less than 100% conversion of TMGa or TEGa into GaCl. Consequently, mixed forms between solely MOCVD and solely HVPE are also possible.

Exemplary embodiments of the invention are explained below with reference to the accompanying drawings, in which:

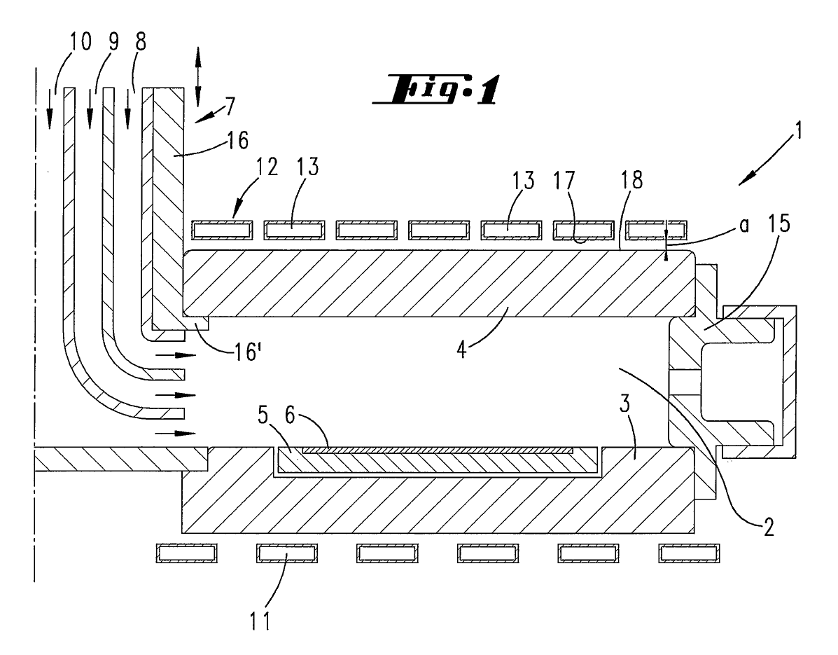

FIG. 1 shows a schematic half-sectional representation of the main elements of the process chamber of a reactor installation 1 in an HVPE operating position,

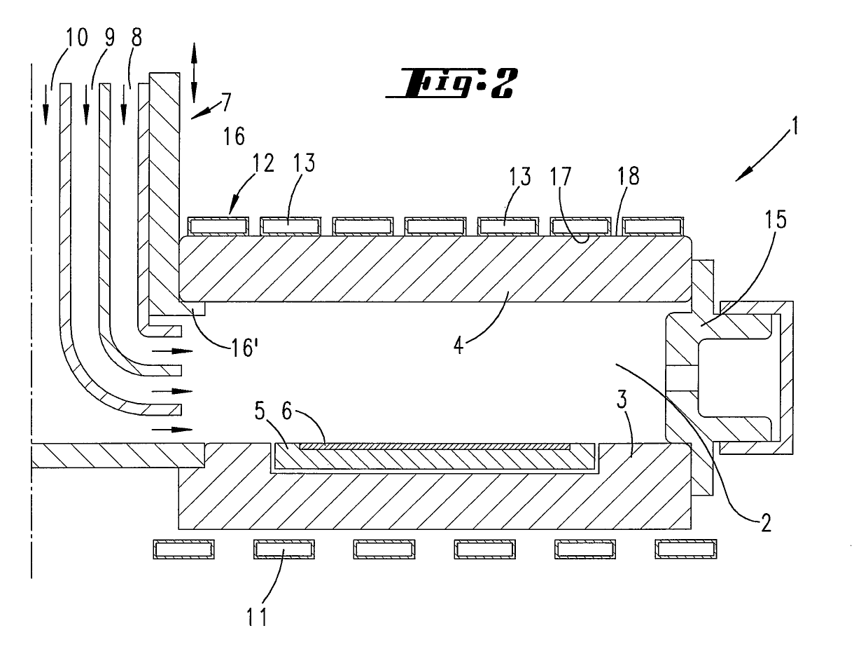

FIG. 2 shows a representation as shown in FIG. 1, the process chamber ceiling 4 having been raised in the direction of the RF heating coil;

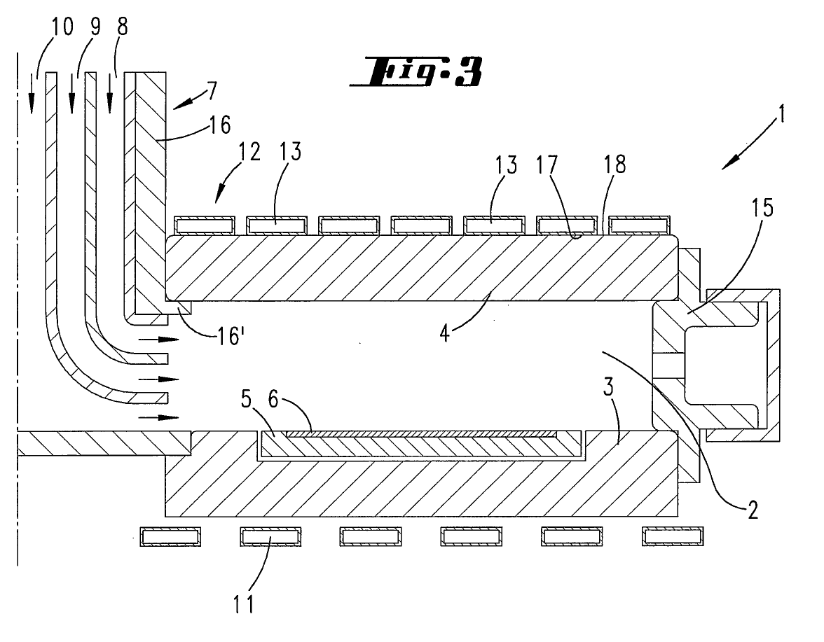

FIG. 3 shows a variant in which the RF heating coil 12 has been lowered in the direction of the process chamber ceiling 4;

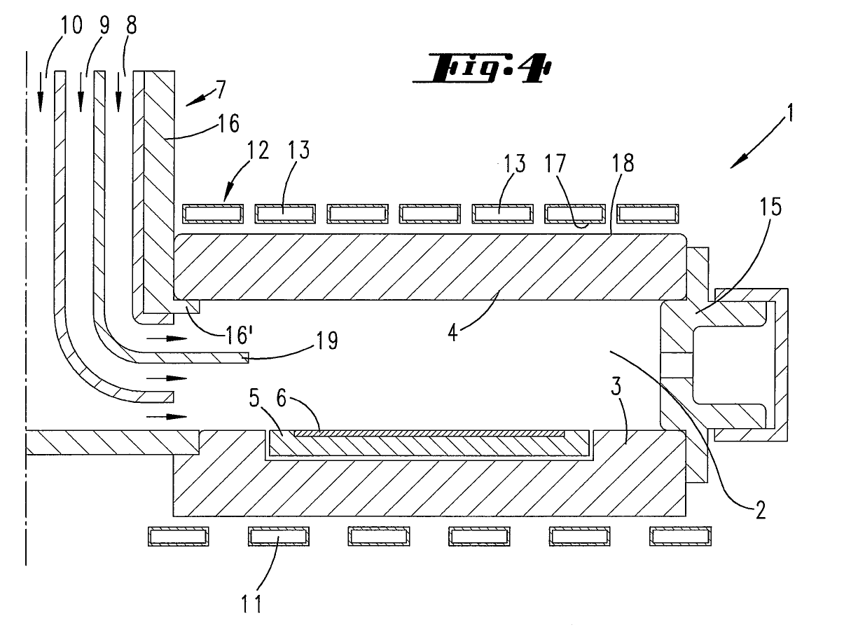

FIG. 4 shows a representation as shown in FIG. 1 with an extended separating wall between two process gas feed channels;

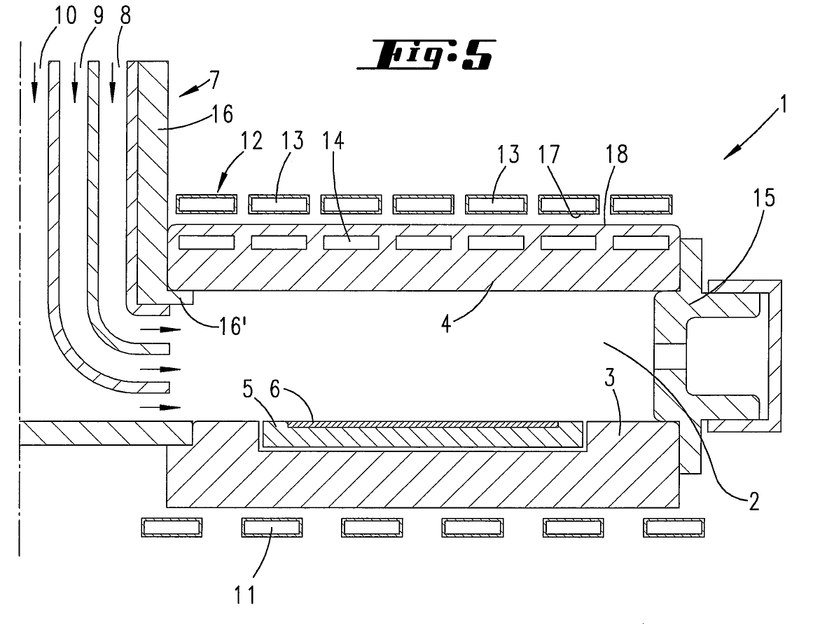

FIG. 5 shows an alternative to the exemplary embodiment represented in FIG. 1 in which coolant channels 14 are provided within the process chamber ceiling 4;

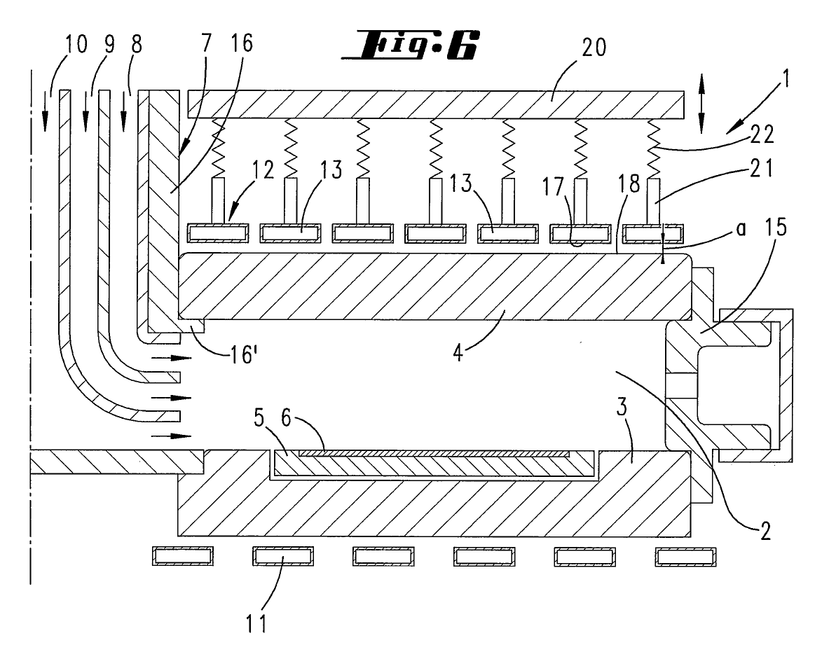

FIG. 6 shows a representation as shown in FIG. 1 of a further alternative and

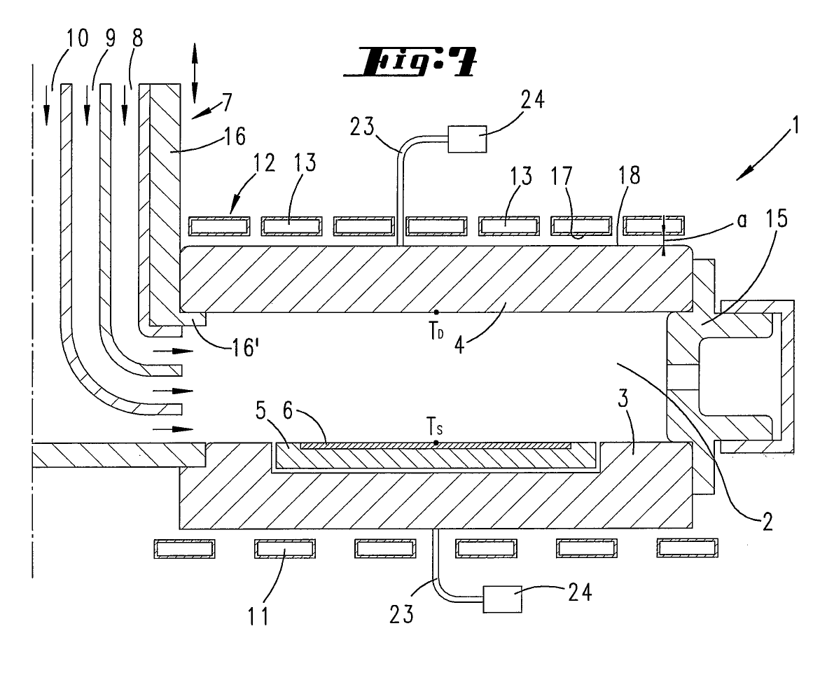

FIG. 7 shows a representation as shown in FIG. 1 of a further alternative.

The apparatus according to the invention is located in a reactor housing that is not represented. The reactor installation designated by the reference numeral 1 substantially comprises a susceptor 3, which is produced from graphite and has the form of a circular disk. Within the susceptor 3 there are a multiplicity of cup-shaped recesses, which are disposed such that they are distributed at equal angular intervals around the center of the susceptor 3. Substrate holders 5 lie in these recesses. The substrate holders 5 have the shape of a circular disk and lie on gas cushions. These gas cushions are also able to drive the substrate holders 5 in rotation. A substrate 6 lies on each of the substrate holders 5. The substrate 6 may be a monocrystalline crystal wafer, on which one or more crystalline layers are to be deposited.

The susceptor 3, lying in a horizontal plane, is heated from below by a susceptor heating device 11. The susceptor heating device 11 may be an RF heating coil, which is formed as a cooling coil. Water flows as coolant through the RF heating coil. Above the susceptor 3 is the process chamber 2, through which the process gases flow in a horizontal direction. The process gases are introduced into the center of the process chamber 2 by means of a gas inlet element 7. The gas inlet element 7 has in the exemplary embodiment a total of three process gas feed lines 8, 9, 10, which are separate from one another and through which the process gases are introduced into the process chamber 2 at different heights.

The gas inlet element 7 is surrounded by a ceiling carrier 16, which has the form of a tube. The ceiling carrier 16 forms a radially outwardly protruding step 16′, on which a ceiling 4 consisting of graphite lies.

Like the susceptor 3, the process chamber ceiling 4 can be heated. For this purpose, a process chamber wall heating device 12 is likewise provided in the form of an RF heating coil, which comprises a cooling coil. Water flows as coolant through the cavities of the RF heating coil 12. In the operating mode represented in FIG. 1, in which an HVPE process can be carried out, the heating coil 12 is at a vertical distance A of approximately 1 mm from the upper side 18 of the process chamber ceiling 4.

The circumferential outer wall of the process chamber 2 is formed by a gas outlet ring 15, through which the process gas can leave the process chamber 2 again.

To be able to carry out an MOCVD process in the process chamber 2, the process chamber ceiling 4 can be cooled. The cooling takes place by the RF heating coil 12. This consequently forms a heating-cooling coil. Either this coil or the process chamber ceiling 4 is movable, so that the heating-cooling coil can be brought into surface contact against the process chamber ceiling 4.

In the case of the variant represented in FIG. 2, the ceiling carrier 16 is displaceable in the vertical direction. A lifting device that is not represented serves for this purpose. By raising the process chamber ceiling from the positional spacing represented in FIG. 1 into the contact position represented in FIG. 2, the upper side 18 of the process chamber ceiling 4 comes into surface contact with the planar underside 17 of the individual turns of the RF heating-cooling coil 12. No current is supplied to the heating-cooling coil 12 in this process mode. However, water flows as coolant through the channels 13, which have a rectangular cross-section. As a result of the large-area surface contact between the underside 17 and the upper side 18, an exchange of heat takes place. Heat can be removed from the process chamber wall 4. As a result, the radiant heat that is transferred from the susceptor 3 to the process chamber ceiling 4 is taken away, with the consequence that the temperature of the process chamber ceiling falls. By variation of the coolant flow through the coolant channel 13, the process chamber ceiling temperature can be adjusted.

In the case of the variant represented in FIG. 3, the heating-cooling coil 12 has been lowered onto the upper side 18 of the process chamber ceiling 4. Both in the operating position shown in FIG. 2 and in the variant shown in FIG. 3, spring elements that are not represented may be provided, acting vertically downward on the heating-cooling coil at various points in order to press the planar underside 17 against the planar upper side 18 of the process chamber ceiling 4.

In the case of the further exemplary embodiment represented in FIG. 5, the process chamber wall heating device 12 need not be displaced to change the operating mode. In the case of this exemplary embodiment, the process chamber ceiling 4 has coolant channels 14, through which a coolant flows. To prevent evaporation of the coolant that is flowing or stationary in the coolant channel 14 when the process chamber ceiling 4 is heated, it is provided that the coolant has an evaporation temperature that lies above the maximum permissible process chamber ceiling temperature. A liquid metal such as gallium or indium comes into consideration for example as the coolant.

With the apparatus described above, a multiplicity of layers can be deposited on a substrate 6 within one process. The layers can be deposited in two different method variants.

If the layer deposition takes place in the MOCVD mode, the process chamber ceiling 4 is cooled in the way described above. Here, the substrate temperature may assume a value between 350° and 700° C. or a greater temperature. The ceiling temperature is much lower than the substrate temperature. It may be between 200° and 500° C. For depositing gallium nitrite, for example, nitrogen or hydrogen and NH₃ are passed through the lowermost process gas feed line 10. Nitrogen or hydrogen and an organometallic material, for example trimethyl gallium, are passed through the middle process gas feed line 9. Instead of trimethyl gallium, however, trimethyl indium or trimethyl aluminum may also be passed through the middle process gas feed line. A carrier gas in the form of nitrogen or hydrogen is likewise passed through the uppermost process gas feed line. In addition, NH₃ may be introduced here into the process chamber. If a different crystal composition is to be deposited, a different hydride, for example arsine or phosphine, may also be introduced into the process chamber. A mixture of the gases described above may also be introduced into the process chamber 2 in order to deposit mixed crystals.

On a layer or a series of layers deposited in this way by the MOCVD process, a layer or a series of layers may be deposited by the HVPE process. For this purpose, the process chamber ceiling 4 is heated in the way described above by means of the heating-cooling device 12. The process temperatures may well be higher here than the process temperatures previously mentioned. The substrate temperature may lie between 1000° and 1200° C. or in a greater temperature range, given above. The temperature of the process chamber ceiling 4 may be the same as the temperature of the susceptor 3. By suitable choice of the energy that is supplied, this temperature may, however, also be greater than the substrate temperature or lower than the substrate temperature. In the case of the HVPE process, nitrogen or hydrogen and a hydride, for example NH₃, is likewise introduced into the process chamber 2 through the lowermost process gas feed line 10. A carrier gas such as hydrogen or nitrogen may be introduced together with an organometallic compound, for example trimethyl gallium, through the middle process gas feed line 9. The organometallic compound decomposes when it enters the process chamber 2. Apart from a carrier gas, HCl may be introduced into the process chamber 2 through the uppermost process gas feed line 8.

In the case of the HVPE process, the spacing a may also be 3 to 5 mm. This distance is advantageous, since a reduced outflow of heat by way of the water cooling takes place as a result of the increased distance a.

MOCVD process steps and HVPE process steps may be performed successively in any desired time sequence.

With the reactor described above, the process chamber 2 can also be cleaned. Serving for this purpose is an etching step, in which both the susceptor 3 and the process chamber ceiling 4 are actively heated. Then, apart from a carrier gas, only HCl is introduced into the process chamber. The introduction of HCl may take place through one of the three process gas feed lines 8, 9, 10 represented.

The heating of the process chamber wall 4 lying opposite the susceptor 3, that is to say for example the process chamber ceiling, takes place with a heating-cooling coil. This forms the antenna of an RF heating device.

In the case of the exemplary embodiment represented in FIG. 6, the spring elements with which the coil 12 acting as a cooling coil interacts are designated by the reference numeral 22. They comprise a multiplicity of compression springs 22, which are supported in the upward direction on a mount 20. In the downward direction, the spring elements 22 are supported on electrical insulators 21. The latter lie on the individual turns of the spiral channel 12. The arrangement represented in FIG. 6 may be provided at equal angular intervals. It is provided in particular that such a spring element 22 acts on the spiral channel 12 every 90°, with an insulator 21 in between. If the coil 12 acting in FIG. 1 as an IR coil is lowered, the mount 20 is initially displaced together with the coil 12 until the underside 17 of the coil makes contact with the upper side 18 of the process chamber ceiling 4. For biasing the compression springs 22, after that the mount 20 moves down a little more. As a result, the individual turns of the coil are pressed by means of spring force against the upper side 18 of the process chamber wall 4. This compensates for thermal expansions of the process chamber ceiling.

In the case of the variant represented in FIG. 7, means by which the susceptor temperature T₅ or the ceiling temperature T_{D} can be measured are represented. These two temperatures are not measured directly, but indirectly by way of a pyrometer 24 in each case. The pyrometer 24 is in each case connected by a light guide to the surface of the process chamber ceiling 4 or the lower surface of the susceptor 3. The temperatures T_{D} and T_{S} can be determined by means of tables or previously established functional relationships. The temperature measuring device shown in FIG. 7 can of course also be provided on an apparatus according to FIG. 6.

All features disclosed are (in themselves) pertinent to the invention. The disclosure content of the associated/accompanying priority documents (copy of the prior patent application) is also hereby incorporated in full in the disclosure of the application, including for the purpose of incorporating features of these documents in claims of the present application.

1. An apparatus for depositing one or more layers on one or more substrates disposed on a susceptor in a process chamber of a reactor, wherein a process chamber wall that can be actively heated by a process chamber heating device lies opposite the susceptor that can be actively heated by a susceptor heating device, and a gas inlet element is provided for introducing process gases into the process chamber, the process chamber heating device having a coolant channel and being situated at a distance from the exterior of the process chamber wall during the active heating of said process chamber wall, characterized in that the coolant channel forms a process chamber wall cooling device whereby the process chamber wall can be selectively actively heated and actively cooled, and a distance between the process chamber wall cooling device and the process chamber wall is variable from a spaced apart heating position to a cooling position by means of a displacement device.

2. An apparatus according to claim 1 wherein the distance between the process chamber wall cooling device and the process chamber wall is near zero when the process chamber wall is in the cooling position so that an exterior of the coolant channel is in surface-area contact with an exterior of the process chamber wall.

3. An apparatus according to claim 1, wherein the process chamber wall heating device is a heating-cooling coil.

4. An apparatus according to claim 3, wherein the displacement device displaces either the process chamber wall in relation to the heating-cooling coil or the heating-cooling coil in relation to the process chamber wall.

5. An apparatus according to claim 4, wherein the process chamber wall that can be displaced toward the heating-cooling coil is a ceiling of the process chamber, and the displacement device is a ceiling carrier carrying the ceiling.

6. An apparatus according to claim 3, further comprising spring elements located to act on the heating-cooling coil, for resiliently urging turns of the heating-cooling coil towards the process chamber wall, thereby to maintain surface contact between an underside of the heating-cooling coil with the and an upper side of the process chamber wall.

7. An apparatus according to claim 1, wherein a substrate is disposed on a substrate holder rotatably associated with the susceptor.

8. (canceled)

9. A Method comprising
depositing a first layer on a substrate disposed on a susceptor in a process chamber of a reactor, the susceptor being actively heated to a susceptor temperature of more than 1000° C., and the first layer being deposited by an HVPE process, wherein a process chamber wall that lies opposite the susceptor is actively heated to a process chamber wall temperature which lies in a range of +/−200° C. above or below the susceptor temperature, and process gases which comprise at least a hydride and a metal halide are introduced into the process chamber by means of a gas inlet element, and
depositing a further layer in the same process chamber using an MOCVD process at a time before or after deposition of the first layer by the HVPE process, wherein process gases for the MOCVD process include at least a hydride and an organometallic compound,
wherein, when carrying out the MOCVD process, the process chamber wall is cooled to a process chamber wall temperature which lies more than 200° C. below the susceptor temperature either by (a) lowering a process chamber heating device from a heating position in which the process chamber heating device is situated at a distance from an exterior of the process chamber wall, to a cooling position spaced apart from the heating position by means of a displacement device, or (b) by flowing a liquid metal having a vaporization point that lies above a highest process chamber wall temperature through coolant channels disposed in the process chamber wall.

10. A method according to claim 9, wherein process gases used in the MOCVD and HVPE processes comprise at least an element of the second or third main group and an element of the fifth or sixth main group.

11. A method according to claim 10, wherein for the MOCVD process, the element of the second or third main group is the organometallic compound and the element of the fifth or sixth main group is the hydride, and for the HVPE process, the same starting materials are used and, in addition, HCl is used as a transporting medium for the element of the organometallic compound.

12. A method according to claim 9, wherein the process chamber wall is heated by means of a heating-cooling coil and is cooled by bringing the process chamber wall into contact with the heating-cooling coil, and flowing a coolant through a cooling channel of the heating-cooling coil.

13. A method according to claim 12, wherein a multiplicity of spring elements disposed offset around the process chamber, are supported in an upward direction on a mount and act in the downward direction on the heating-cooling coil.

14. A method according to claim 9, wherein with a heated or cooled process chamber ceiling, a halide is introduced into the process chamber together with an organometallic component of an element of the third main group, the concentration of the halide being so small that complete conversion of the organometallic component into a metal chloride does not take place.
